(19) United States
(12) Patent Application Publication
(10) Pub. No.: US 2026/0114032 A1
(43) Pub. Date: Apr. 23, 2026

(54) INTEGRATED CIRCUIT DEVICES

(71) Applicant: Samsung Electronics Co., Ltd., Suwon-si (KR)

(72) Inventors: Youngseok Song, Suwon-si (KR); Seunghyun Song, Suwon-si (KR); Ahyoung Kim, Suwon-si (KR); Yonghee Park, Suwon-si (KR); Pilkwang Kim, Suwon-si (KR); Jeesoo Chang, Suwon-si (KR); Doyoung Choi, Suwon-si (KR)

(21) Appl. No.: 19/229,281

(22) Filed: Jun. 5, 2025

(30) Foreign Application Priority Data
Oct. 18, 2024 (KR) 10-2024-0143264

(51) Int. Cl. H10D 84/83; H10D 64/23; H10D 64/27; H10D 89/10

(52) U.S. Cl. CPC H10D 84/832; H10D 64/254; H10D 64/518; H10D 89/10

(57) ABSTRACT

An integrated circuit device comprises: a first nanosheet stack; a first source/drain connected to the first nanosheet stack; a first contact on the first source/drain; a second nanosheet stack; a second source/drain connected to the second nanosheet stack; a second contact on the second source/drain; and an insulating layer between the first and second nanosheet stacks, wherein the first contact comprises a first contact body extending in a first direction and a first contact protrusion protruding from the first contact body, the second contact comprises a second contact body extending in the first direction and a second contact protrusion protruding from the second contact body, and the first contact protrusion and the second contact protrusion are spaced apart from each other with the insulating layer therebetween in the first direction and each of the first contact protrusion and the second contact protrusion has an asymmetrical shape in the first direction.

### CROSS-REFERENCE TO RELATED APPLICATIONS

This application is based on and claims priority under 35 U.S.C. § 119 to Korean Patent Application No. 10-2024-0143264, filed on Oct. 18, 2024, in the Korean Intellectual Property Office, the disclosure of which is incorporated by reference herein in its entirety.

### BACKGROUND OF THE INVENTION

The inventive concept relates to integrated circuit devices, and more particularly, to integrated circuit devices including contact plugs.

As the integration density of integrated circuit devices increases, the size of the integrated circuit devices decreases, and the scaling of the integrated circuit devices becomes challenging. Therefore, new methods involving structural changes may be needed to improve the performance of integrated circuit devices, and integrated circuit devices equipped with a transistor having a new structure, such as a multi-gate transistor, have been proposed.

### SUMMARY OF THE INVENTION

The inventive concept may provide integrated circuit devices with a reduced standard cell area.

According to an aspect of the inventive concept, there is provided an integrated circuit device including a first standard cell that comprises a first nanosheet stack, a first source/drain that is electrically connected to the first nanosheet stack, and a first contact on the first source/drain; a second standard cell that comprises a second nanosheet stack, a second source/drain that is electrically connected to the second nanosheet stack, and a second contact on the second source/drain, wherein the second standard cell is adjacent to the first standard cell in a first direction; and an insulating layer that extends in a vertical direction and overlaps a cell boundary in the vertical direction between the first standard cell and the second standard cell in the first direction, wherein the vertical direction intersects the first direction, wherein the first contact comprises a first contact body that extends in the first direction and a first contact protrusion that protrudes from an upper surface of the first contact body in the vertical direction, wherein the second contact comprises a second contact body that extends in the first direction and a second contact protrusion that protrudes from an upper surface of the second contact body in the vertical direction, and wherein the first contact protrusion and the second contact protrusion are spaced apart from each other with the insulating layer therebetween in the first direction and each of the first contact protrusion and the second contact protrusion has an asymmetrical shape in the first direction.

According to another aspect of the inventive concept, there is provided an integrated circuit device including a first standard cell that comprises a first nanosheet stack, a first source/drain that is electrically connected to the first nanosheet stack, and a first gate electrode that extends around the first nanosheet stack; a second standard cell that comprises a second nanosheet stack, a second source/drain that is electrically connected to the second nanosheet stack, and a second gate electrode that extends around the second nanosheet stack, wherein the second standard cell is adjacent to the first standard cell in a first direction; and an insulating layer that extends in a vertical direction and overlaps a cell boundary in the vertical direction between the first standard cell and the second standard cell in the first direction, wherein the vertical direction intersects the first direction, wherein the first gate electrode comprises a first electrode body that extends in the first direction and a first electrode protrusion that protrudes from an upper surface of the first electrode body in the vertical direction, wherein the second gate electrode includes a second electrode body that extends in the first direction and a second electrode protrusion that protrudes from an upper surface of the second electrode body in the vertical direction, and wherein the first electrode protrusion and the second electrode protrusion are spaced apart from each other with the insulating layer therebetween in the first direction and each of the first electrode protrusion and the second electrode protrusion has an asymmetrical shape in the first direction.

According to another aspect of the inventive concept, there is provided an integrated circuit device including a first nanosheet stack and a second nanosheet stack on active regions of a substrate, wherein the first nanosheet stack and the second nanosheet stack are spaced apart from each other in a first direction that is parallel with an upper surface of the substrate; a first source/drain and a second source/drain that are electrically connected to the first nanosheet stack and the second nanosheet stack, respectively; a first gate electrode and a second gate electrode that extend in the first direction, wherein the first gate electrode and the second gate electrode extend around the first nanosheet stack and the second nanosheet stack, respectively; a first metal layer above the first gate electrode and the second gate electrode; a first contact on the first source/drain, wherein the first contact comprises a first contact body that extends in the first direction and a first contact protrusion that protrudes from an upper surface of the first contact body in a vertical direction that is perpendicular to the upper surface of the substrate; and a second contact on the second source/drain, wherein the second contact comprises a second contact body that extends in the first direction and a second contact protrusion that protrudes from an upper surface of the second contact body in the vertical direction, wherein the first contact protrusion and the second contact protrusion are spaced apart from each other in the first direction and each of the first contact protrusion and the second contact protrusion has an asymmetrical shape in the first direction.

### BRIEF DESCRIPTION OF THE DRAWINGS

Embodiments will be more clearly understood from the following detailed description taken in conjunction with the accompanying drawings in which:

FIG. 1 is a layout illustrating an integrated circuit device according to some embodiments;

FIG. 2 is an example of a cross-sectional view taken along line X1-X1′ of FIG. 1, according to some embodiments;

FIG. 3 is an example of a cross-sectional view taken along line X2-X2′ of FIG. 1, according to some embodiments;

FIGS. 4A, 4B, 4C, and 4D are cross-sectional views illustrating a method of manufacturing the integrated circuit device shown in FIG. 1, according to some embodiments;

FIG. 5 is an example of the cross-section view taken along line X1-X1′ of FIG. 1, according to some embodiments;

FIG. 6 is a layout illustrating an integrated circuit device according to some embodiments;

FIG. 7 is a cross-sectional view taken along line X3-X3′ of FIG. 6, according to some embodiments;

FIG. 8 is a cross-sectional view taken along line X4-X4′ of FIG. 6, according to some embodiments;

FIG. 9 is a layout illustrating an integrated circuit device according to some embodiments;

FIG. 10 is a cross-sectional view taken along line X5-X5′ of FIG. 9, according to some embodiments;

FIG. 11 is a layout illustrating an integrated circuit device according to some embodiments;

FIG. 12 is a cross-sectional view taken along line X6-X6′ of FIG. 11, according to some embodiments;

FIGS. 13A, 13B, 13C, and 13D are cross-sectional views illustrating a method of manufacturing the integrated circuit device shown in FIG. 11, according to some embodiments;

FIG. 14 is an example of the cross-sectional view taken along line X6-X6′ of FIG. 11, according to some embodiments;

FIG. 15 is a layout illustrating an integrated circuit device according to some embodiments;

FIG. 16 is a layout illustrating an integrated circuit device according to some embodiments;

FIG. 17 is a layout illustrating an integrated circuit device according to some embodiments; and

FIG. 18 is a flowchart illustrating a method of manufacturing an integrated circuit, according to some embodiments.

### DETAILED DESCRIPTION OF THE INVENTION

Hereinafter, embodiments will be described with reference to the accompanying drawings. In the drawings, like reference numerals may denote like elements unless described otherwise, and repeated descriptions thereof may be omitted. The terms “first,” “second,” etc., may be used herein merely to distinguish one component, layer, direction, etc. from another. The term “connected” may be used herein to refer to a physical and/or electrical connection. When components or layers are referred to herein as “directly” on, or “in direct contact” or “directly connected,” no intervening components or layers are present. Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. Spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures.

In the present specification, an X-axis direction may be referred to as a first direction, a Y-axis direction may be referred to as a second direction, and a Z-axis direction may be referred to as a vertical direction. A plane formed by an X-axis and a Y-axis may be referred to as a horizontal plane, elements arranged in a positive (+) Z-axis direction relative to other elements may be referred to as being located above the other elements, and elements arranged in a negative (−) Z-axis direction relative to other elements may be referred to as being located below the other elements.

An integrated circuit may be designed by arranging a plurality of standard cells. The term “standard cell” refers to a unit of a layout of an integrated circuit and may also be referred to as a “cell” in some embodiments. A standard cell may be designed such that the standard cell may include a plurality of transistors to perform a predefined function. This standard cell methodology may involve preparing standard cells having various functions in advance and combining the standard cells to design dedicated large-scale integrated circuits tailored to customer or user specifications. Standard cells may be pre-designed and verified before being registered in a standard cell library, and integrated circuits may be designed using the standard cells through computer-aided design (CAD), logic design, placement, and routing.

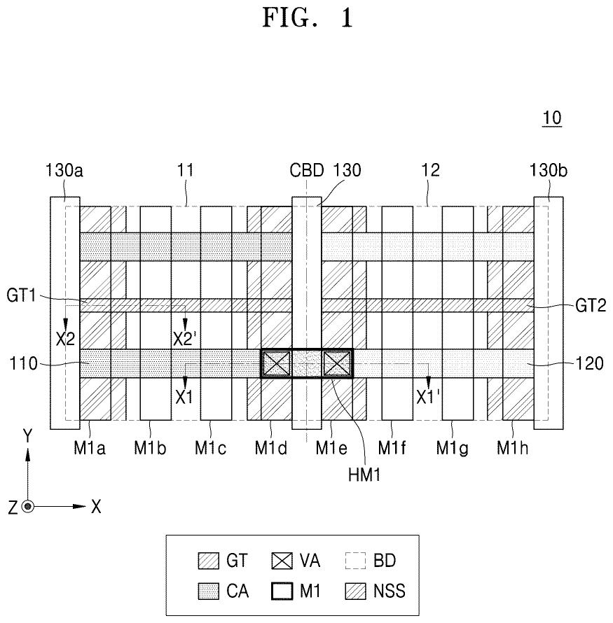

FIG. 1 is a layout illustrating an integrated circuit device 10 according to some embodiments.

Referring to FIG. 1, the integrated circuit device 10 may include logic cells or standard cells, and each standard cell may include a transistor. For example, the integrated circuit device 10 may include a first standard cell 11 and a second standard cell 12 that are adjacent to each other in the first direction. The first and second standard cells 11 and 12 may each be defined by boundaries BD. In the present specification, a boundary BD extending in the second direction between the first and second standard cells 11 and 12 (in the first direction) is referred to as a “cell boundary CBD.” The first direction and the second direction may intersect (e.g., cross) each other. For instance, the first and second standard cells 11 and 12 may form AND gates, NAND gates, OR gates, NOR gates, exclusive OR (XOR) gates, exclusive NOR (XNOR) gates, inverters, OR/AND/INVERTER (OAI) gates, AND/OR/INVERTER (AOI) gates, adders, buffers, multiplexers, flip-flops, latches, or the like.

The first and second standard cells 11 and 12 may each include a gate-all-around (GAA) field effect transistor. The GAA transistor may include a channel or active region in the shape of a nanowire or nanosheet, and a gate extending around (e.g., surrounding) the active region. For instance, the integrated circuit device 10 may include nanosheet stacks NSS, contacts CA, vias VA, gate electrodes GT, and a first metal layer M1 to implement GAA transistors. In some embodiments, each of the first and second standard cells 11 and 12 may include various transistors such as fin field effect transistors (FinFETs) or planar transistors, and embodiments described below may be applied to GAA transistors, FinFETs, planar transistors, or the like.

Each of the nanosheet stacks NSS may include a plurality of nanosheets that are apart from each other in the vertical direction and extend in the second direction. The integrated circuit device 10 may further include an insulating layer 130 overlapping the cell boundary CBD (in the vertical direction) and extending in the second direction. In this case, the insulating layer 130 may extend in the vertical direction and may thus be referred to as an insulating wall or a sheet separation wall. Hereinafter, the insulating layer 130 may be referred to as an insulating wall 130. In addition, the integrated circuit device 10 may further include an insulating wall 130a overlapping a left boundary BD of the first standard cell 11 (in the vertical direction) and extending in the second direction, and an insulating wall 130b overlapping a right boundary BD of the second standard cell 12 (in the vertical direction) and extending in the second direction. The left boundary BD of the first standard cell 11 may be opposite to the cell boundary CBD in the first direction with respect to the first standard cell 11. The right boundary BD of the second standard cell 12 may be opposite to the cell boundary CBD in the first direction with respect to the second standard cell 12. The cell boundary CBD may be between the left boundary BD of the first standard cell 11 and the right boundary BD of the second standard cell 12 in the first direction.

According to the current embodiment, the insulating walls 130, 130a, and 130b may be used to implement forksheet transistors from the nanosheet stacks NSS. As described above, the insulating wall 130 may form a spacer between the nanosheet stacks NSS, thereby reducing the areas of transistors and the areas of the first and second standard cells 11 and 12. Furthermore, the insulating wall 130 may be formed along the cell boundary CBD with the nanosheet stacks NSS being on both sides (e.g., two opposite sides in the first direction) of the insulating wall 130, thereby reducing the distance between the nanosheet stacks NSS and achieving area scaling down.

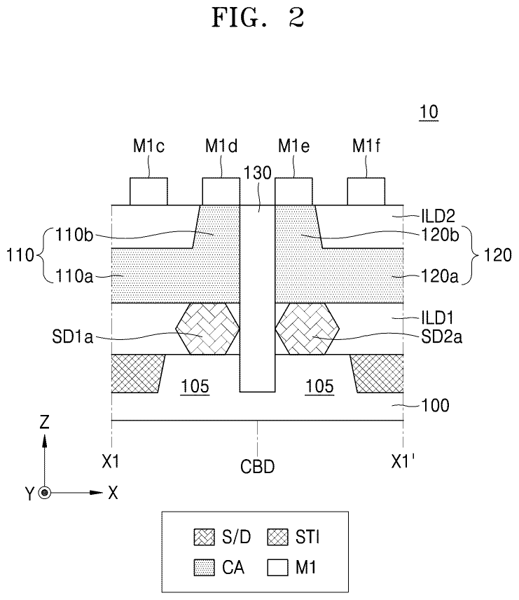

The contacts CA may each extend in the first direction. For example, the first standard cell 11 may include a first contact 110, and the second standard cell 12 may include a second contact 120. The first and second contacts 110 and 120 may be apart from each other in the first direction. The first contact 110 may overlap the second contact 120 in the first direction. For instance, the first and second contacts 110 and 120 may be arranged in a line. The vias VA may be arranged above the first and second contacts 110 and 120, respectively. In an embodiment, each of the first and second contacts 110 and 120 may include a contact body extending in the first direction and a contact protrusion extending from the contact body and corresponding to a vias VA. A contact pattern may be selectively recessed to form the contact bodies and the contact protrusions as described above. This may improve a short margin between contact plugs adjacent to the contact protrusions corresponding to the vias VA, for example, a short margin between a gate contact and a source/drain contact. Embodiments corresponding to this are described with reference to FIGS. 2, 3, 4A, 4B, 4C, and 4D.

The gate electrodes GT may include first and second gate electrodes GT1 and GT2, each extending in the first direction. For example, the first standard cell 11 may include the first gate electrode GT1, and the second standard cell 12 may include the second gate electrode GT2. The first and second gate electrodes GT1 and GT2 may be apart from each other in the first direction. the first gate electrode GT1 may overlap the second gate electrode GT2 in the first direction. For instance, the first and second gate electrodes GT1 and GT2 may be arranged in a line.

The first metal layer M1 may be provided on (above) the first and second standard cells 11 and 12. The first metal layer M1 may include first metal lines M1a, M1b, M1c, and M1d and second metal lines M1e, M1f, M1g, and M1h that are apart from each other in the first direction and extend in the second direction. The first metal lines M1a, M1b, M1c, and M1d may be arranged on (above) the first standard cell 11, and thus, the first standard cell 11 may have a 4-track structure. The second metal lines M1e, M1f, M1g, and M1h may be arranged on (above) the second standard cell 12, and thus, the second standard cell 12 may have a 4-track structure.

The first metal lines M1a, M1b, M1c, and M1d may be arranged within the boundaries BD of the first standard cell 11 as inbound-type metal lines and may not overlap the cell boundary CBD (in the vertical direction). The second metal lines M1e, M1f, M1g, and M1h may be arranged within the boundaries BD of the second standard cell 12 as inbound-type metal lines and may not overlap the cell boundary CBD (in the vertical direction).

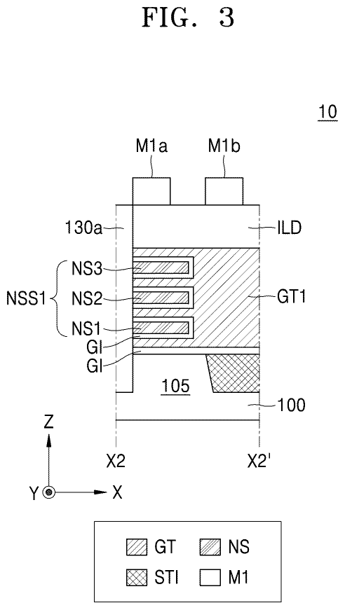

According to the current embodiment, the vias VA may be formed through an etching process using a first hard mask or a first mask pattern HM1. For example, the first mask pattern HM1 may be implemented as a bar-type rectangle extending in the first direction, but the inventive concept is not limited thereto. The first mask pattern HM1 may be implemented in any shape as long as the length of the first mask pattern HM1 in the first direction is greater than the length of the first mask pattern HM1 in the second direction. The first mask pattern HM1 may overlap the cell boundary CBD (in the vertical direction), and the vias VA adjacent to the cell boundary CBD may be formed through an etching process using the first mask pattern HM1. As a result, the vias VA may be asymmetrically etched relative to the cell boundary CBD, and thus, the vias VA may have asymmetrical shapes in the first direction. The asymmetrical shapes of the vias VA are further described with reference to FIGS. 2 and 3.

FIG. 2 is an example of a cross-sectional view taken along line X1-X1′ of FIG. 1, according to some embodiments. FIG. 3 is an example of a cross-sectional view taken along line X2-X2′ of FIG. 1, according to some embodiments.

Referring to FIGS. 1 to 3, the integrated circuit device 10 may include a substrate 100 and active regions 105. The active regions 105 may each extend in the second direction and may be defined by device isolation layers (for example, shallow trench isolation (STI)). Each of the active regions 105 may be adjacent to at least one of the device isolation layers. The active regions 105, which are part of the substrate 100 as described above, may correspond to vertically protruding portions of the substrate 100 and may thus be referred to as fin-type active regions.

A nanosheet stack NSS1 may include first, second, and third nanosheets NS1, NS2, and NS3 overlapping an active region 105 in the vertical direction. However, the inventive concept is not limited thereto, and the number of nanosheets included in the nanosheet stack NSS1 may vary depending on embodiments. The first gate electrode GT1 may extend around (e.g., surround) the nanosheet stack NSS1 and extend in the first direction. The first gate electrode GT1 may include a metal, a metal nitride, a metal carbide, and/or a combination thereof.

Gate dielectric layers GI may be provided between the nanosheet stack NSS1 and the first gate electrode GT1. A gate dielectric layer GI may also be provided between the substrate 100 and the first gate electrode GT1. For example, the gate dielectric layers GI may each have a stacked structure of an interface layer and a high-k dielectric layer. An interlayer insulating layer ILD may be disposed on (above) the first gate electrode GT1.

The first standard cell 11 may further include a first source/drain SD1a on (above) an active region 105, and the second standard cell 12 may further include a second source/drain SD2a on (above) an active region 105. The first contact 110 may be disposed between the first source/drain SD1a and at least one of the first metal lines (e.g., the first metal line M1d) and may electrically connect the first source/drain SD1a and the at least one of the first metal lines (e.g., the first metal line M1d) to each other. The second contact 120 may be disposed between the second source/drain SD2a and at least one of the second metal lines (e.g., the second metal line M1e) and may electrically connect the second source/drain SD2a and the at least one of the second metal lines (e.g., the second metal line M1e) to each other. A first interlayer insulating layer ILD1 may be disposed on (above) the substrate 100 and the first and second source/drains SD1a and SD2a, and a second interlayer insulating layer ILD2 may be disposed on (above) the first and second contacts 110 and 120.

The first contact 110 may include a first contact body 110a extending in the first direction on (above) the first source/drain SD1a and a first contact protrusion 110b protruding from an upper surface of the first contact body 110a (in the vertical direction). For example, the first contact body 110a and the first contact protrusion 110b may form a single body without an interface therebetween. In other words, the first contact body 110a and the first contact protrusion 110b may be portions of a single body including the same material. The second contact 120 may include a second contact body 120a extending in the first direction on (above) the second source/drain SD2a and a second contact protrusion 120b protruding from an upper surface of the second contact body 120a (in the vertical direction). For example, the second contact body 120a and the second contact protrusion 120b may form a single body without an interface therebetween. In other words, the second contact body 120a and the second contact protrusion 120b may be portions of a single body including the same material.

The first and second contact protrusions 110b and 120b may be separated from each other by the insulating wall 130 and may each have an asymmetrical shape in the first direction. For example, an etching process may be performed using the first mask pattern HM1 (which will be described in detail later) to asymmetrically form the first and second contact protrusions 110b and 120b based on the cell boundary CBD, and as a result, the first and second contact protrusions 110b and 120b may each have an asymmetrical shape (in the first direction).

For example, a first angle between a left side (farther side from the cell boundary CBD in the first direction) of the first contact protrusion 110b and a horizontal plane of the substrate 100 may be less than a second angle between a right side (closer side to the cell boundary CBD in the first direction) of the first contact protrusion 110b and the horizontal plane of the substrate 100. For instance, the first angle may be in a range of (about) 0° to less than (about) 90°, and the second angle may be (about) 90° and/or greater than the first angle. For example, a third angle between a right side (farther side from the cell boundary CBD in the first direction) of the second contact protrusion 120b and the horizontal plane of the substrate 100 may be less than a fourth angle between a left side (closer side to the cell boundary CBD in the first direction) of the second contact protrusion 120b and the horizontal plane of the substrate 100. For instance, the third angle may be in a range of (about) 0° to less than (about) 90°, and the fourth angle may be (about) 90° and/or greater than the third angle.

At least one of the first metal lines (e.g., the first metal line M1d) may be disposed on (above) the first contact protrusion 110b, and the first source/drain SD1a may be electrically connected to the at least one of the first metal lines (e.g., the first metal line M1d) through the first contact 110 (the first contact body 110a and/or the first contact protrusion 110b). For example, the first contact protrusion 110b may correspond to a via VA. An upper surface of the first contact protrusion 110b may be directly in contact with a lower surface of the at least one of the first metal lines (e.g., the first metal line M1d), and thus, the first contact 110 may be directly connected to the at least one of the first metal lines (e.g., the first metal line M1d) without an additional structure therebetween. Because the first contact protrusion 110b and the at least one of the first metal lines (e.g., the first metal line M1d) are connected to each other as described above, interface resistance between the first contact protrusion 110b and adjacent contact plugs may be reduced.

At least one of the second metal lines (e.g., the second metal line M1e) may be disposed on (above) the second contact protrusion 120b, and the second source/drain SD2a may be electrically connected to the at least one of the second metal lines (e.g., the second metal line M1e) through the second contact 120 (the second contact body 120a and/or the second contact protrusion 120b). For example, the second contact protrusion 120b may correspond to a via VA. An upper surface of the second contact protrusion 120b may be directly in contact with a lower surface of the at least one of the second metal lines (e.g., the second metal line M1e), and thus, the second contact 120 may be directly connected to the at least one of the second metal lines (e.g., the second metal line M1e) without an additional structure therebetween. Because the second contact protrusion 120b and the at least one of the second metal lines (e.g., the second metal line M1e) are connected to each other as described above, interface resistance between the second contact protrusion 120b and adjacent contact plugs may be reduced.

In the related art, an etching process may be performed using a plurality of mask patterns respectively corresponding to vias VA to form two vias VA facing each other across a cell boundary CBD. In this case, wiring metal lines may be designed to be apart from the cell boundary CBD to ensure a distance defined by design rules between contacts and/or contact plugs. A metal line overlapping the cell boundary CBD is additionally provided to maintain a metal pitch together with the distance between contacts and the distance between contact plugs. As a result, five metal lines, exceeding the number of wiring metal lines actually required, are arranged above each standard cell. Thus, each standard cell has a 5-track structure, leading to an increase in the area of each standard cell and an increase in the area of an integrated circuit device.

According to the current embodiment, the first and second contact bodies 110a and 120a may first be separated from each other based on the insulating wall 130 that is formed for device isolation. Then, two vias VA adjacent to the cell boundary CBD may be etched in one time using one mask pattern, that is, the first mask pattern HM1 (which will be described in detail later), thereby forming the first and second contact protrusions 110b and 120b. When the vias VA face each other across the cell boundary CBD as described above, because the first and second contact bodies 110a and 120a are already separated from each other by the insulating wall 130, node separation between cells may be achieved by forming the first and second contact protrusions 110b and 120b based on one mask pattern, that is, the first mask pattern HM1.

Owing to this, the distance between the vias VA facing each other across the cell boundary CBD may be reduced compared to the related art, and thus, a metal line overlapping the cell boundary CBD may not be added. Therefore, the metal pitch of the first metal layer M1 may be increased, reducing the resistance or capacitance of the first metal layer M1. In addition, because a metal line overlapping the cell boundary CBD is not required, the first metal layer M1 of each standard cell may have a 4-track structure. Thus, the area of each standard cell may be reduced, and the area of the integrated circuit device 10 may also be reduced.

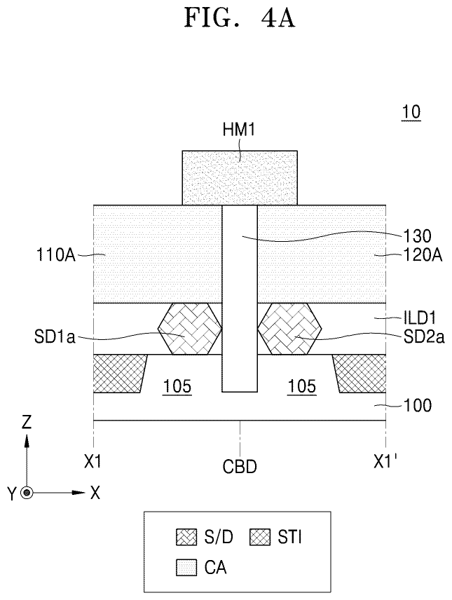

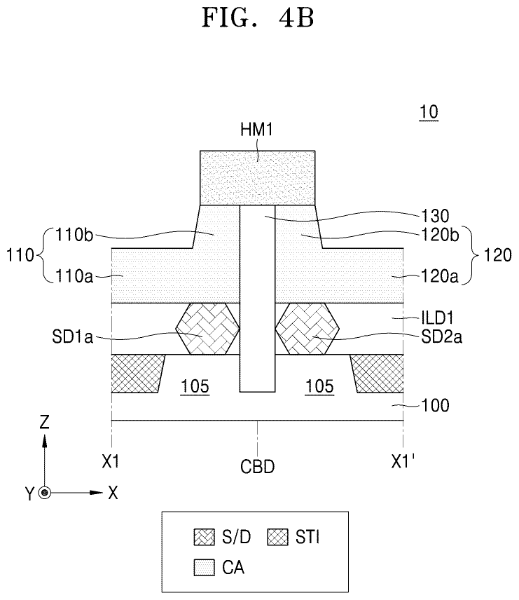

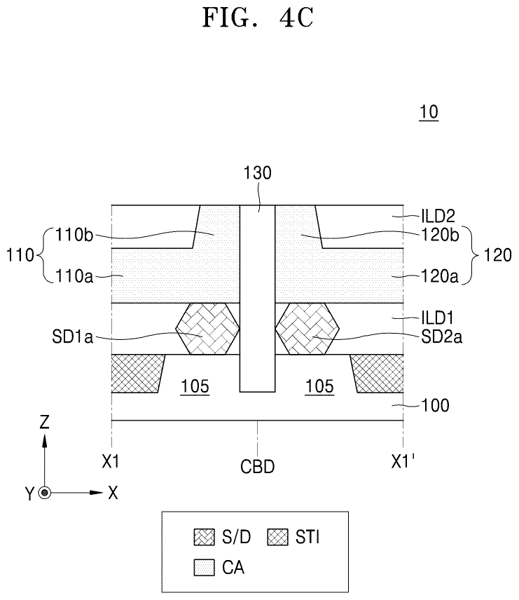

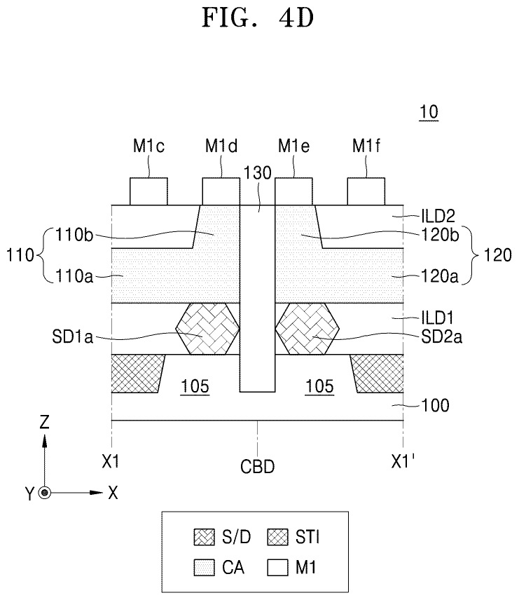

FIGS. 4A, 4B, 4C, and 4D are cross-sectional views illustrating a method of manufacturing the integrated circuit device 10 shown in FIG. 1, according to some embodiments. Here, FIGS. 4A, 4B, 4C, and 4D correspond to cross-sectional views taken along lines X1-X1′ line of FIG. 1.

Referring to FIGS. 1 and 4A, a substrate 100 may have an upper surface extending in the first direction and the second direction. The substrate 100 may include, for example, a semiconductor material such as a Group IV semiconductor, a Group III-V compound semiconductor, and/or a Group II-VI compound semiconductor. For example, the Group IV semiconductor may include silicon, germanium, and/or silicon-germanium. The substrate 100 may be provided as a bulk wafer, an epitaxial layer, a silicon-on-insulator (SOI) layer, a semiconductor-on-insulator (SeOI) layer, or the like.

Device isolation layers STI may define active regions 105 in the substrate 100. For example, an active region 105 of the substrate 100 may be adjacent the device isolation layer STI in the substrate 100. In some embodiments, the device isolation layers STI may further include regions each extending deeper into a lower portion of the substrate 100 with a step difference. The device isolation layers STI may expose upper surfaces of the active regions 105. In some embodiments, the device isolation layers STI may partially expose upper portions of the active regions 105. In embodiments, the device isolation layers STI may have upper surfaces that are curved such that the levels of the upper surfaces increase in directions toward the active regions 105. The device isolation layers STI may include an insulating material. For example, the device isolation layers STI may include an oxide, a nitride, and/or a combination thereof.

The active regions 105 may be defined in the substrate 100 by the device isolation layers STI and may each extend in the second direction. The active regions 105 may have a structure protruding from the substrate 100 (in the vertical direction). In some embodiments, the upper portions of the active regions 105 may protrude to a certain height above the upper surfaces of the device isolation layers STI. The active regions 105 may be part of the substrate 100 or may include epitaxial layers grown from the substrate 100. However, the active regions 105 may be partially recessed at both sides of gate electrodes GT (refer to FIG. 1) to form recessed regions, and source/drains S/D may be positioned in the recessed regions.

In embodiments, the active regions 105 may each include a doped region. The doped region may correspond to a well region of a transistor. In a P-type field effect transistor (PFET), the doped region may include an N-type dopant such as phosphorus (P), arsenic (As), and/or antimony (Sb). In an N-type field effect transistor (NFET), the doped region may include a P-type dopant such as boron (B), gallium (Ga), and/or aluminum (Al). The doped regions may be at a certain depth from the upper surfaces of the active regions 105 and the substrate 100.

First and second source/drains SD1a and SD2a may be disposed on (above) the active regions 105. For example, the first and second source/drains SD1a and SD2a may be disposed in the recessed regions that are formed by partially recessing the upper portions of the active regions 105. The first and second source/drains SD1a and SD2a may be in contact with a plurality of nanosheets of a nanosheet stack NSS while overlapping (e.g., covering) lateral surfaces of the nanosheets. A first interlayer insulating layer ILD1 may be formed on (above) the first and second source/drains SD1a and SD2a.

Conductive patterns 110A and 120A may be formed on (above) the first and second source/drains SD1a and SD2a and the first interlayer insulating layer ILD1. An insulating wall 130 may be formed between the conductive patterns 110A and 120A. In some embodiments, a barrier pattern may further be formed between a region including the first and second source/drains SD1a and SD2a and the first interlayer insulating layer ILD1 and a region including the conductive patterns 110A and 120A. For example, the barrier pattern may include a metal layer/metal nitride layer. The conductive patterns 110A and 120A may include, for example, aluminum, copper, tungsten, molybdenum, and/or cobalt. A first mask pattern HM1 may be formed on (above) the conductive patterns 110A and 120A and the insulating wall 130. The first mask pattern HM1 may include, for example, photoresist, silicon nitride, and/or silicon oxynitride.

Referring to FIG. 4B, upper portions of the conductive patterns 110A and 120A exposed through the first mask pattern HM1 may be etched to form recessed regions. As a result, a first contact protrusion 110b may be formed in the upper portion of the conductive pattern 110A, and a lower portion of the conductive pattern 110A may be defined as a first contact body 110a. In this case, the first contact body 110a and the first contact protrusion 110b may form a first contact 110. In addition, a second contact protrusion 120b may be formed in the upper portion of the conductive pattern 120A, and a lower portion of the conductive pattern 120A may be defined as a second contact body 120a. In this case, the second contact body 120a and the second contact protrusion 120b may form a second contact 120. The recessed regions may be formed through a dry etching process and/or a wet etching process.

In the related art, two vias may be formed by performing an etching process using two mask patterns. In this case, each of the two vias may have a (substantially) symmetrical shape in the first direction. For example, the two mask patterns may be formed as square-type pillars, and thus, the two vias may each be etched in a (substantially) symmetrical shape. However, according to the current embodiment, the first and second contact protrusions 110b and 120b may be formed by performing an etching process using a single mask pattern, that is, the first mask pattern HM1. For example, the first mask pattern HM1 may be formed as a bar-type pillar, and thus, each of the first and second contact protrusions 110b and 120b may be etched in an asymmetrical shape.

Referring to FIG. 4C, the first mask pattern HM1 may be removed, and then, a second interlayer insulating layer ILD2 may be formed by forming an interlayer insulating layer (at least partially) filling the recessed regions and performing a planarization process. An upper surface of the second interlayer insulating layer ILD2 may be at the same level as (may be coplanar with) upper surfaces of the first and second contact protrusions 110b and 120b. The second interlayer insulating layer ILD2 may include, for example, SiO₂, SiN, SiC, SiOC, and/or AlOₓ. Referring to FIG. 4D, a metal layer may be formed on (above) the second interlayer insulating layer ILD2 and then patterned to form a metal layer M1 including, for example, first metal lines M1c and M1d and second metal lines M1e and M1f.

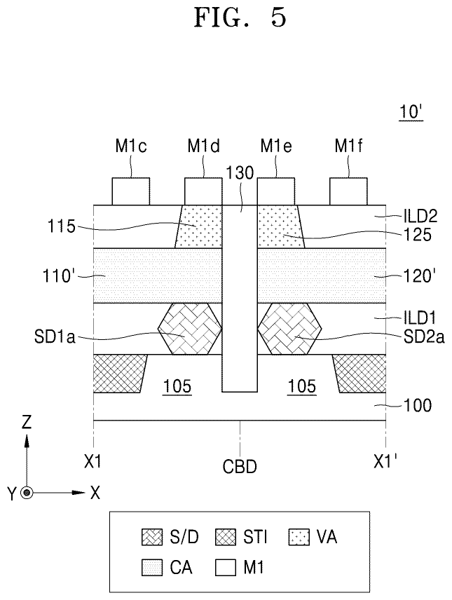

FIG. 5 is an example of the cross-sectional view taken along line X1-X1′ of FIG. 1, according to some embodiments. Herein, the term “level”, “vertical level”, “height”, or the like may refer to a relative location with respect to a reference element in the vertical direction. A level, a vertical level, height, or the like may be a distance from the lower surface of the substrate 100 in the vertical direction. For example, a higher level may mean a farther distance from the lower surface of the substrate 100 in the vertical direction, and a lower level may mean a closer distance to the lower surface of the substrate 100 in the vertical direction.

Referring to FIG. 5, an integrated circuit device 10′ may correspond to a modification example of the integrated circuit device 10 described with reference to FIG. 2. For example, a first contact 110′ may be disposed on (above) a first source/drain SD1a, and a first via 115 may be disposed on (above) the first contact 110′. The first source/drain SD1a may be (electrically) connected to at least one of the first metal lines (e.g., a first metal line M1d) through the first contact 110′ and the first via 115. A second contact 120′ may be disposed on (above) a second source/drain SD2a, and a second via 125 may be disposed on (above) the second contact 120′. The second source/drain SD2a may be (electrically) connected to at least one of the second metal lines (e.g., a second metal line M1e) through the second contact 120′ and the second via 125.

An interface may be between the first contact 110′ and the first via 115, and an interface may be between the second contact 120′ and the second via 125. As described above, the inventive concept is not limited to embodiments in which a source/drain is connected to a metal line through a single-body contact, that is, through a contact body and a contact protrusion, but encompasses embodiments in which a source/drain is connected to a metal line through a contact and a via.

The first and second vias 115 and 125 may correspond to the vias VA shown in FIG. 1 and may be formed through an etching process using a first mask pattern HM1 (refer to FIG. 1). Thus, the first and second vias 115 and 125 may each have an asymmetrical shape based on the cell boundary CBD. In other words, the first and second vias 115 and 125 may each have an asymmetrical shape in the first direction. According to the current embodiment, the first and second vias 115 and 125 may be formed through an etching process using a single mask pattern, that is, the first mask pattern HM1. For example, the first mask pattern HM1 may be formed as a bar-type pillar, and thus, the first and second vias 115 and 125 may each be etched in an asymmetrical shape.

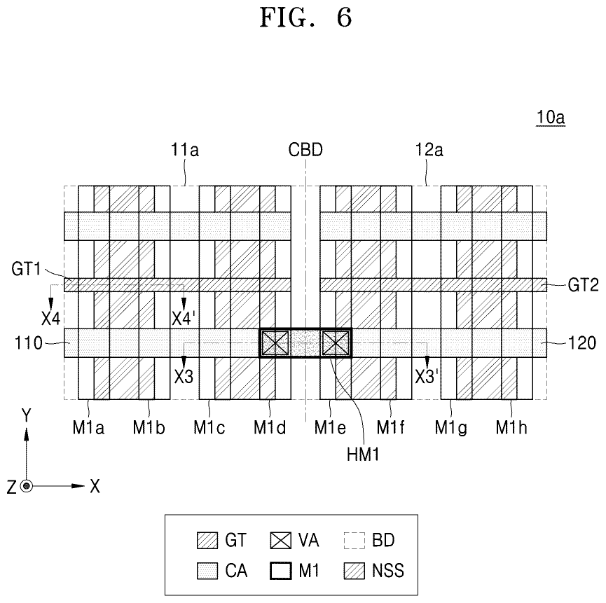

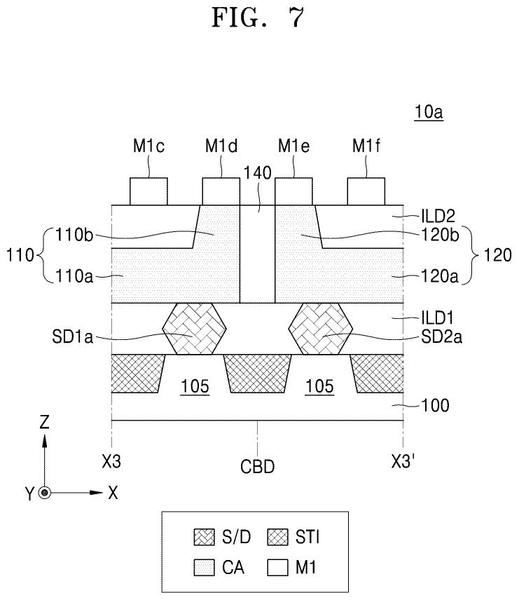

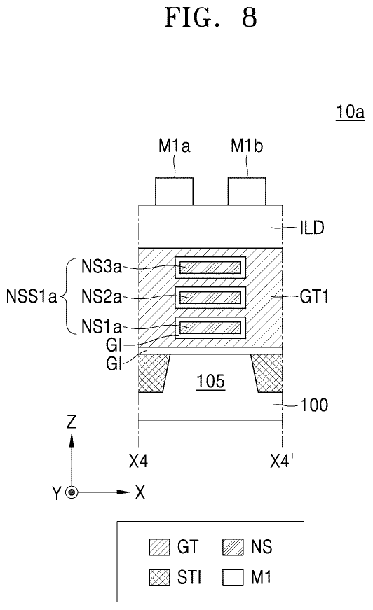

FIG. 6 is a layout illustrating an integrated circuit device 10a according to some embodiments. FIG. 7 is a cross-sectional view taken along line X3-X3′ of FIG. 6, according to some embodiments. FIG. 8 is a cross-sectional view taken along line X4-X4′ of FIG. 6, according to some embodiments.

Referring to FIGS. 6 to 8, the integrated circuit device 10a may include a first standard cell 11a and a second standard cell 12a that are adjacent to each other in the first direction. In the current embodiment, each of the first and second standard cells 11a and 12a may include GAA transistors such as multi-bridge channel field effect transistors (MBCFETs). The integrated circuit device 10a may correspond to a modification example of the integrated circuit device 10 shown in FIG. 1, and the descriptions provided with reference to FIGS. 1 to 5 may also apply to the current embodiment.

For example, the first standard cell 11a may include a pair of nanosheet stacks NSS extending in the second direction, and the second standard cell 12a may include a pair of nanosheet stacks NSS extending in the second direction. For instance, a nanosheet stack NSS1a may include first, second, and third nanosheets NS1a, NS2a, and NS3a overlapping an active region 105 in the vertical direction. However, the inventive concept is not limited thereto, and the number of nanosheets included in the nanosheet stack NSS1a may vary depending on embodiments.

First and second contact protrusions 110b and 120b may be separated from each other by an insulating layer 140 and may each have an asymmetrical shape in the first direction. For example, the insulating layer 140 may correspond to a contact cut pattern separating first and second contacts 110 and 120 from each other. For example, the first and second contact protrusions 110b and 120b may be asymmetrically etched based on a cell boundary CBD through an etching process using a first mask pattern HM1, and thus, the first and second contact protrusions 110b and 120b may each have an asymmetrical shape. According to the current embodiment, the first and second contact protrusions 110b and 120b may be formed through an etching process using a single mask pattern, that is, the first mask pattern HM1. For example, the first mask pattern HM1 may be formed as a bar-type pillar, and as a result, the first and second contact protrusions 110b and 120b may each be etched in an asymmetrical shape.

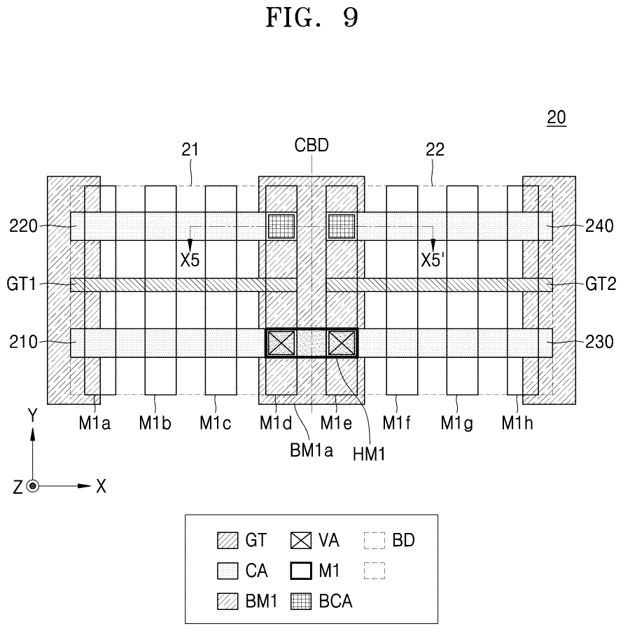

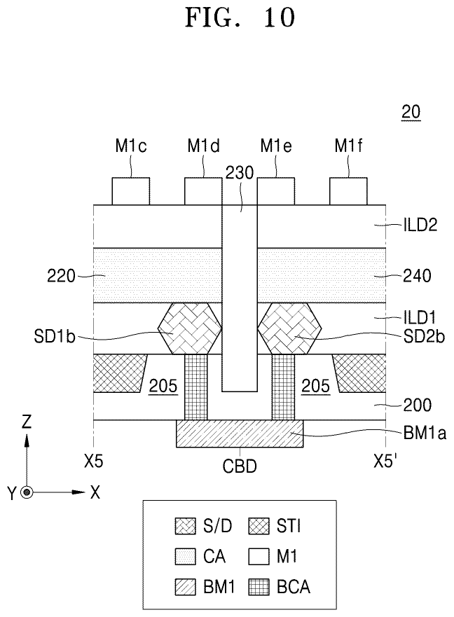

FIG. 9 is a layout illustrating an integrated circuit device 20 according to some embodiments. FIG. 10 is a cross-sectional view taken along line X5-X5′ of FIG. 9, according to some embodiments.

Referring to FIGS. 9 and 10 together, the integrated circuit device 20 may include a first standard cell 21 and a second standard cell 22 that are adjacent to each other in the first direction. For example, the first and second standard cells 21 and 22 may correspond to modification examples of the first and second standard cells 11 and 12 shown in FIG. 1, respectively and may each include forksheet transistors. For example, the first and second standard cells 21 and 22 may correspond to modification examples of the first and second standard cells 11a and 12a shown in FIG. 6, respectively and may each include GAA transistors such as MBCFETs. The descriptions provided with reference to FIGS. 1 to 8 may also apply to the current embodiment.

The integrated circuit device 20 may include a front side wiring layer such as a first metal layer M1 and a backside wiring layer such as a first backside metal layer BM1, and a power distribution network (PDN) may be implemented using the front side wiring layer and the backside wiring layer. In this case, the first metal layer M1 may be disposed on (above) (an upper surface of) a substrate 200 in the vertical direction, and the first backside metal layer BM1 may be disposed on (below) (a lower surface of) the substrate 200 in the vertical direction. Thus, signals and/or powers applied to the integrated circuit device 20 may be transmitted through the first metal layer M1, that is, a front side PDN (FSPDN), and/or through the first backside metal layer BM1, that is, a backside PDN (BSPDN). Therefore, compared to a structure in which wiring is arranged only on a front side of a substrate, the current embodiment may reduce routing complexity and may reduce the length of each wire or via, thereby improving the performance of the integrated circuit device 20.

In an embodiment, the first metal layer M1 may be used for signal wiring, and the first backside metal layer BM1 may be used for power wiring. The number of metal lines included in the first metal layer M1 may be reduced by supplying power through the first backside metal layer BM1 as described above, thereby further decreasing the area of each standard cell and achieving area scaling down.

The first backside metal layer BM1 may include a first backside wiring pattern BM1a extending in the second direction and overlapping the cell boundary CBD (in the vertical direction). The first backside wiring pattern BM1a may be (electrically) connected to first and second source/drains SD1b and SD2b through backside contacts BCA. The backside contacts BCA may be disposed on (above) the first backside metal layer BM1 and may extend into (extend through) the substrate 200 in the vertical direction. For example, the first and second source/drains SD1b and SD2b may correspond to source regions that receive power voltage or ground voltage through the first backside wiring pattern BM1a.

The first standard cell 21 may include contacts 210 and 220 each extending in the first direction, and the second standard cell 22 may include contacts 230 and 240 each extending in the first direction. The contacts 210 and 230 may be implemented same as (or similarly to) the contacts 110 and 120 described with reference to FIG. 1. That is, the contact 210 may include a first contact body and a first contact protrusion on (above) the first contact body, and the contact 230 may include a second contact body and a second contact protrusion on (above) the second contact body. The first and second contact protrusions may be formed through an etching process using a first mask pattern HM1 and may thus each have an asymmetrical shape based on the cell boundary CBD. For example, the first and second contact protrusions may each have an asymmetrical shape in the first direction.

The first standard cell 21 may include the first source/drain SD1b on (above) an active region 205, and the second standard cell 22 may include the second source/drain SD2b on (above) an active region 205. The contact 220 may be disposed on (above) the first source/drain SD1b, and the contact 240 may be disposed on (above) the second source/drain SD2b. A first interlayer insulating layer ILD1 may be disposed on (above) the substrate 200 and the first and second source/drains SD1b and SD2b, and a second interlayer insulating layer ILD2 may be disposed on (above) the contacts 220 and 240.

In an embodiment, the first and second source/drains SD1b and SD2b may receive power voltage or ground voltage from the first backside wiring pattern BM1a through the backside contacts BCA. Therefore, the contacts 220 and 240 may not be electrically connected to the first metal layer M1. However, the inventive concept is not limited thereto, and in some embodiments, the contacts 220 and 240 may be electrically connected to the first metal layer M1 and receive power voltage or ground voltage from both the first backside wiring pattern BM1a and the first metal layer M1 to further improve the performance of the integrated circuit device 20.

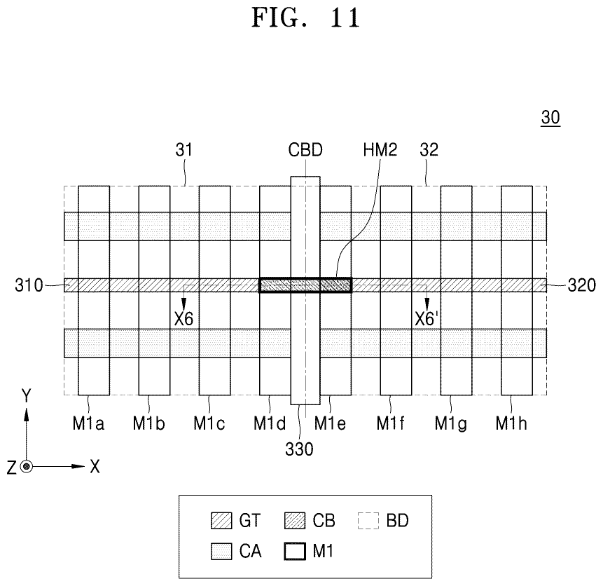

FIG. 11 is a layout illustrating an integrated circuit device 30 according to some embodiments.

Referring to FIG. 11, the integrated circuit device 30 may include a first standard cell 31 and a second standard cell 32 that are adjacent to each other in the first direction. For example, the first and second standard cells 31 and 32 may each include GAA transistors such as forksheet transistors or MBCFETs. The first standard cell 31 may include contacts CA and a first gate electrode 310 that extend in the first direction, and first metal lines M1a, M1b, M1c, and M1d may be disposed on (above) the first standard cell 31. The second standard cell 32 may include contacts CA and a second gate electrode 320 that extend in the first direction, and second metal lines M1e M1f, M1g, and M1h may be disposed on (above) the second standard cell 32.

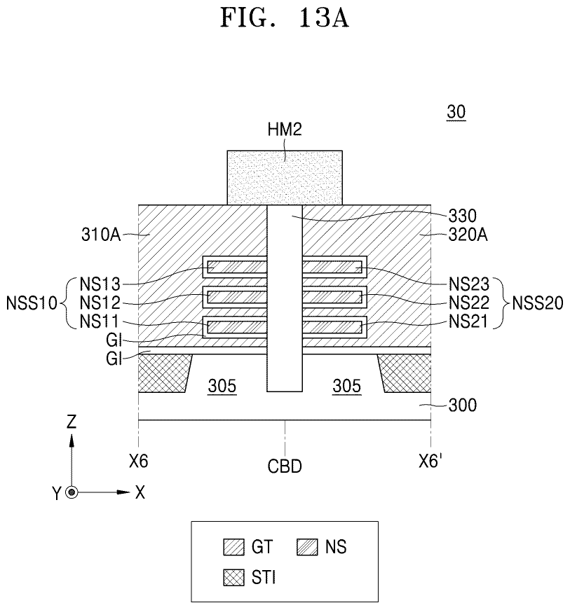

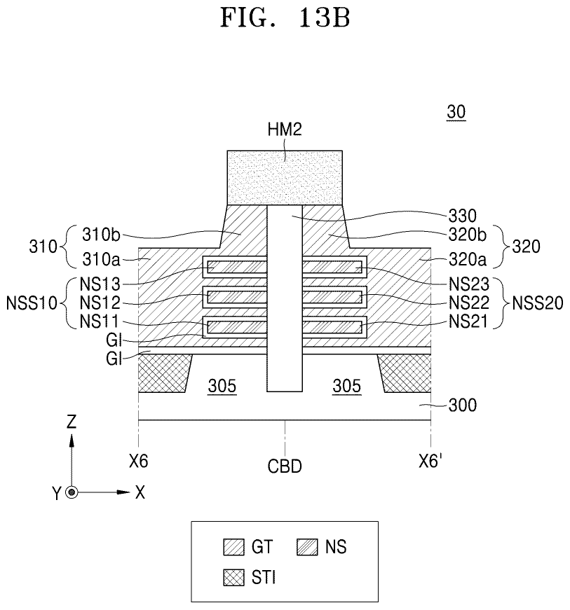

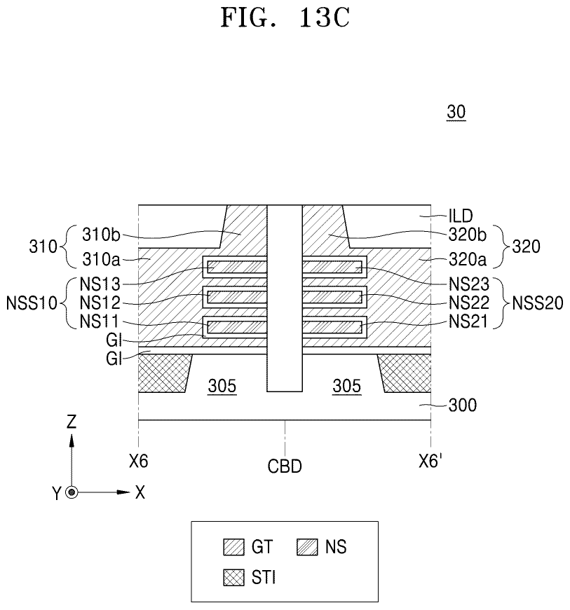

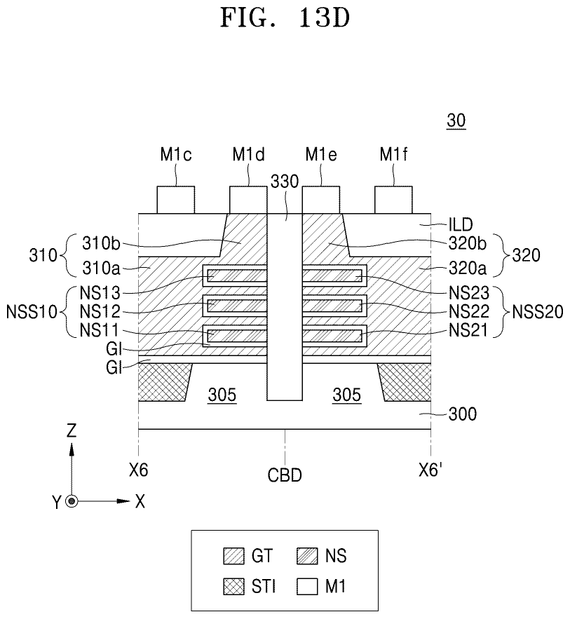

The first and second gate electrodes 310 and 320 may be apart from each other in the first direction. The first and second gate electrodes 310 and 320 may overlap in the first direction. For example, the first and second gate electrodes 310 and 320 may be arranged in a line. Gate contacts CB may be disposed on (above) the first and second gate electrodes 310 and 320, respectively. In an embodiment, each of the first and second gate electrodes 310 and 320 may include an electrode body extending in the first direction and an electrode protrusion protruding from the electrode body (in the vertical direction) and corresponding to the gate contact CB. The electrode body and the electrode protrusion may be formed as described above by selectively recessing a gate pattern, and thus, a short margin between contact plugs adjacent to the electrode protrusion corresponding to the gate contact CB, for example, a short margin between gate contacts or source/drains, may be improved. Relevant embodiments are described below with reference to FIGS. 13A, 13B, 13C, and 13D.

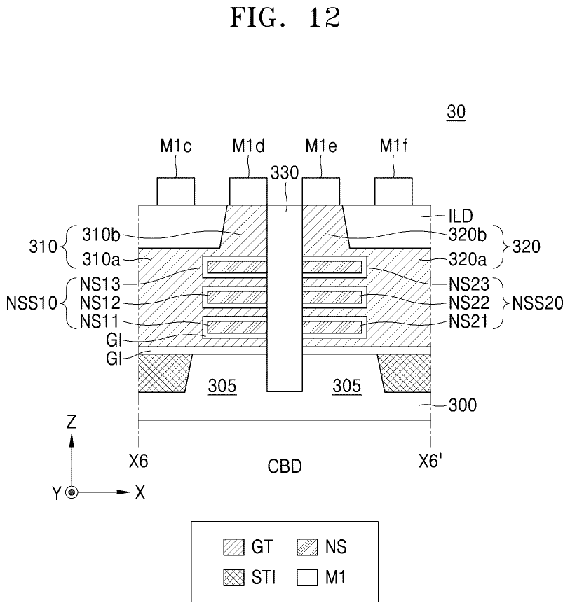

According to the current embodiment, the gate contacts CB may be formed through an etching process using a second hard mask or a second mask pattern HM2. For example, the second mask pattern HM2 may be implemented as a bar-type rectangle extending in the first direction, but the inventive concept is not limited thereto. The second mask pattern HM2 may be implemented in any shape, provided that the length of the shape in the first direction is greater than the length of the shape in the second direction. The second mask pattern HM2 may overlap a cell boundary CBD (in the vertical direction), and the gate contacts CB adjacent to the cell boundary CBD may be formed through an etching process using the second mask pattern HM2. As a result, the gate contacts CB may be asymmetrically etched based on the cell boundary CBD, and thus, the gate contacts CB may each have an asymmetrical shape in the first direction. The asymmetrical shapes of the gate contacts CB are further described below with reference to FIG. 12.

FIG. 12 is a cross-sectional view taken along line X6-X6′ of FIG. 11, according to some embodiments.

Referring to FIGS. 11 and 12 together, the integrated circuit device 30 may include a substrate 300 and active regions 305. The active regions 305 may each extend in the second direction and may be defined by device isolation layers STI. The first standard cell 31 may include a first nanosheet stack NSS10, and the second standard cell 32 may include a second nanosheet stack NSS20. The first and second nanosheet stacks NSS10 and NSS20 may be apart from each other by a sheet separation wall or an insulating wall 330. In this manner, the integrated circuit device 30 may include forksheet transistors.

The first nanosheet stack NSS10 may include a first nanosheet NS11, a second nanosheet NS12, and a third nanosheet NS13 that overlap an active region 305 in the vertical direction. The second nanosheet stack NSS20 may include a first nanosheet NS21, a second nanosheet NS22, and a third nanosheet NS23 that overlap an active region 305 in the vertical direction. However, the inventive concept is not limited thereto, and the number of nanosheets included in each of the first and second nanosheet stacks NSS10 and NSS20 may vary depending on embodiments.

The first gate electrode 310 may include a first electrode body 310a extending in the first direction and a first electrode protrusion 310b protruding from an upper surface of the first electrode body 310a (in the vertical direction). For example, the first electrode body 310a and the first electrode protrusion 310b may form a single body without an interface therebetween. That is, the first electrode body 310a and the first electrode protrusion 310b may be portions of a single body including the same material. The second gate electrode 320 may include a second electrode body 320a extending in the first direction and a second electrode protrusion 320b protruding from an upper surface of the second electrode body 320a (in the vertical direction). For example, the second electrode body 320a and the second electrode protrusion 320b may form a single body without an interface therebetween. That is, the second electrode body 320a and the second electrode protrusion 320b may be portions of a single body including the same material.

The first electrode body 310a may extend around (e.g., surround) the first nanosheet stack NSS10 and extend in the first direction. The second electrode body 320a may extend around (e.g., surround) the second nanosheet stack NSS20 and extend in the first direction. The first and second gate electrodes 310 and 320 may include, for example, a metal, a metal nitride, a metal carbide, and/or a combination thereof. Gate dielectric layers GI may be arranged between the first nanosheet stack NSS10 and the first electrode body 310a, and gate dielectric layers GI may be arranged between the second nanosheet stack NSS20 and the second electrode body 320a. In addition, a gate dielectric layer GI may also be arranged between the substrate 300 and the first and second electrode bodies 310a and 320a. For example, the gate dielectric layers GI may each have a stacked structure of an interface layer and a high-k dielectric layer. An interlayer insulating layer ILD may be disposed on (above) the first and second gate electrodes 310 and 320.

The first and second electrode protrusions 310b and 320b may be apart from each other by the insulating wall 330 and may each have an asymmetrical shape in the first direction. For example, the first and second electrode protrusions 310b and 320b may be asymmetrically etched based on the cell boundary CBD through an etching process using the second mask pattern HM2, and thus, the first and second electrode protrusions 310a and 310b may each have an asymmetrical shape (in the first direction).

For example, a first angle between a left side (a farther side from the insulating wall 330 in the first direction) of the first electrode protrusion 310b and a horizontal plane of the substrate 300 may be less than a second angle between a right side (a closer side to the insulating wall 330 in the first direction) of the first electrode protrusion 310b and the horizontal plane of the substrate 300. For example, the first angle may be in a range of (about) 0° to less than (about) 90°, and the second angle may be (about) 90° and/or greater than the first angle. A third angle between a right side (a farther side from the insulating wall 330 in the first direction) of the second electrode protrusion 320b and the horizontal plane of the substrate 300 may be less than a fourth angle between a left side (a closer side to the insulating wall 330 in the first direction) of the second electrode protrusion 320b and the horizontal plane of the substrate 300. For instance, the third angle may be in a range of (about) 0° to less than (about) 90°, and the fourth angle may be (about) 90° and/or greater than the third angle.

At least one of the first metal lines (e.g., the first metal line M1d) may be disposed on (above) the first electrode protrusion 310b, and the first electrode body 310a may be electrically connected to the at least one of the first metal lines (e.g., the first metal line M1d) through the first electrode protrusion 310b. For example, the first electrode protrusion 310b may correspond to a gate contact CB. An upper surface of the first electrode protrusion 310b may be directly in contact with a lower surface of the at least one of the first metal lines (e.g., the first metal line M1d), and thus, the first gate electrode 310 may be directly connected to the at least one of the first metal lines (e.g., the first metal line M1d) without an additional structure therebetween. Because the first electrode protrusion 310b and the at least one of the first metal lines (e.g., the first metal line M1d) are (electrically) connected to each other as described above, interface resistance between the first electrode protrusion 310b and adjacent contact plugs may be reduced.

At least one of the second metal lines (e.g., the second metal line M1e) may be disposed on (above) the second electrode protrusion 320b, and the second electrode body 320a may be electrically connected to the at least one of the second metal lines (e.g., the second metal line M1e) through the second electrode protrusion 320b. For example, the second electrode protrusion 320b may correspond to a gate contact CB. An upper surface of the second electrode protrusion 320b may be directly in contact with a lower surface of the at least one of the second metal lines (e.g., the second metal line M1e), and thus, the second gate electrode 320 may be directly connected to the at least one of the second metal lines (e.g., the second metal line M1e) without additional structures therebetween. Because the second electrode protrusion 320b and the at least one of the second metal lines (e.g., the second metal line M1e) are (electrically) connected to each other as described above, interface resistance between the second electrode protrusion 320b and adjacent contact plugs may be reduced.

In the related art, an etching process is performed using a plurality of mask patterns respectively corresponding to gate contacts CB, and thus, two gate contacts CB facing each other across the cell boundary CBD are formed. However, according to the current embodiment, the first and second electrode bodies 310a and 320a may first be separated from each other based on the insulating wall 330 that is formed for device isolation. The first and second electrode protrusions 310b and 320b may be formed by etching two gate contacts CB adjacent to the cell boundary CBD in one time using a single mask pattern, that is, the second mask pattern HM2. When the gate contacts CB face each other across the cell boundary CBD as described above, because the first and second electrode bodies 310a and 320a are already separated from each other by the insulating wall 330, node separation between cells may be achieved by forming the first and second electrode protrusions 310b and 320b based on one mask pattern, that is, the second mask pattern HM2.

Therefore, the distance between the gate contacts CB facing each other across the cell boundary CBD may be reduced compared to the related art, and thus, a metal line overlapping the cell boundary CBD (in the vertical direction) may not be required. As a result, the metal pitch of a first metal layer M1 may be increased, and thus, the resistance or capacitance of the first metal layer M1 may be reduced. In addition, because a metal line overlapping the cell boundary CBD is not required, the first metal layer M1 of each standard cell may have a 4-track structure. Thus, the area of each standard cell may be reduced, and the area of the integrated circuit device 30 may also be reduced.

FIGS. 13A, 13B, 13C, and 13D are cross-sectional views illustrating a method of manufacturing the integrated circuit device 30 shown in FIG. 11, according to some embodiments. The descriptions provided with reference to FIGS. 4A, 4B, 4C, and 4D may also apply to the current embodiment.

Referring to FIGS. 11 and 13A, a substrate 300 may have an upper surface extending in the first direction and the second direction. The substrate 300 may be implemented in a manner (substantially) similar to or same as the substrate 100 described with reference to FIG. 2. Device isolation layers STI may define active regions 305 in the substrate 300. The active regions 305 may be defined within the substrate 300 by the device isolation layers STI and may each extend in the second direction. The active regions 305 may be implemented in a manner (substantially) similar to or same as the active regions 105 described with reference to FIG. 2.

First and second nanosheet stacks NSS10 and NSS20 may be formed on (above) the active regions 305 and may be apart from each other by an insulating wall 330 (in the first direction). A gate dielectric layer GI may be formed on upper surfaces of the active regions 305 and the device isolation layers STI, and gate dielectric layers GI may be formed on the first and second nanosheet stacks NSS10 and NSS20. Gate patterns 310A and 320A may be formed on the gate dielectric layers GI. A second mask pattern HM2 may be formed on (above) the gate patterns 310A and 320A and the insulating wall 330. The second mask pattern HM2 may include, for example, photoresist, silicon nitride, and/or silicon oxynitride.

Referring to FIG. 13B, upper portions of the gate patterns 310A and 320A exposed through the second mask pattern HM2 may be etched to form recessed regions. As a result, a first electrode protrusion 310b may be formed in the upper portion of the gate pattern 310A, and a lower portion of the gate pattern 310A may be defined as a first electrode body 310a. In this case, the first electrode body 310a and the first electrode protrusion 310b may form a first gate electrode 310. A second electrode protrusion 320b may be formed in the upper portion of the gate pattern 320A, and a lower portion of the gate pattern 320A may be defined as a second electrode body 320a. In this case, the second electrode body 320a and the second electrode protrusion 320b may form a second gate electrode 320. The recessed regions may be formed through a dry etching process and/or a wet etching process.

In the related art, two gate contacts are formed through an etching process using two mask patterns. In this case, each of the two gate contacts may have a (substantially) symmetrical shape in the first direction. For example, the two mask patterns may be formed as square-type pillars, resulting in the two gate contacts each being etched in a (substantially) symmetrical shape. However, according to the current embodiment, the first and second electrode protrusions 310b and 320b may be formed through an etching process using a single mask pattern, that is, the second mask pattern HM2. For example, the second mask pattern HM2 may be formed as a bar-type pillar, resulting in the first and second electrode protrusions 310b and 320b each being etched in an asymmetrical shape (in the first direction).

Referring to FIG. 13C, the second mask pattern HM2 may be removed, and then, an interlayer insulating layer ILD may be formed by forming an interlayer insulating layer (at least partially) filling the recessed regions and performing a planarization process. An upper surface of the interlayer insulating layer ILD may be at the same level as (coplanar with) upper surfaces of the first and second electrode protrusions 310b and 320b. The interlayer insulating layer ILD may include a material including, for example, SiO₂, SiN, SiC, SiOC, and/or AlOx. Referring to FIG. 13D, a metal layer may be formed on (above) the interlayer insulating layer ILD and then patterned to form a first metal layer M1 including first metal lines M1c and M1d and second metal lines M1e and M1f.

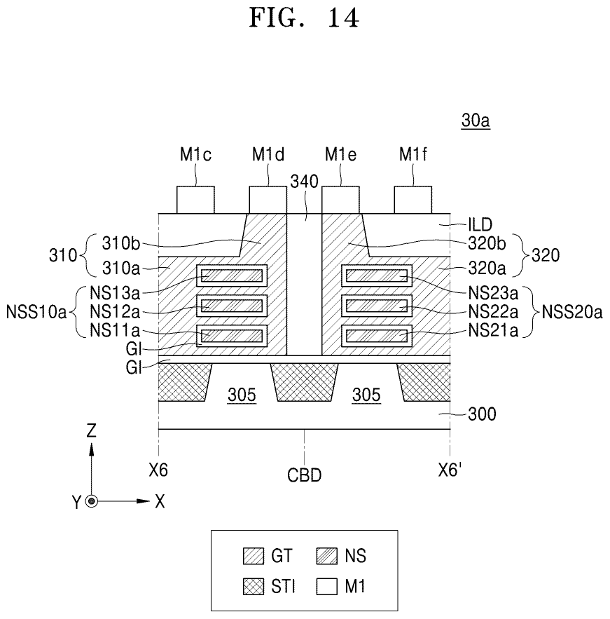

FIG. 14 is an example of the cross-sectional view taken along line X6-X6′ of FIG. 11, according to some embodiments.

Referring to FIG. 14, an integrated circuit device 30a may include GAA transistors such as MBCFETs. For example, a first standard cell 31 may include a first nanosheet stack NSS10a, and a second standard cell 32 may include a second nanosheet stack NSS20a. For instance, the first nanosheet stack NSS10a may include a first nanosheet NS11a, a second nanosheet NS12a, and a third nanosheet NS13a that overlap an active region 305 in the vertical direction. The second nanosheet stack NSS20a may include a first nanosheet NS21a, a second nanosheet NS22a, and a third nanosheet NS23a that overlap an active region 305 in the vertical direction Z. However, the inventive concept is not limited thereto, and the number of nanosheets included in each of the first and second nanosheet stacks NSS10a and NSS20a may vary depending on embodiments.

First and second electrode protrusions 310b and 320b may be separated from each other by an insulating layer 340 and may each have an asymmetrical shape in the first direction. For example, the insulating layer 340 may correspond to a gate cut pattern (for example, a CT pattern) separating first and second gate electrodes 310 and 320 from each other. For example, the first and second electrode protrusions 310b and 320b may be asymmetrically etched based on a cell boundary CBD through an etching process using a second mask pattern HM2 (refer to FIG. 11), and thus, each of the first and second electrode protrusions 310b and 320b may have an asymmetrical shape (in the first direction). According to the current embodiment, the first and second electrode protrusions 310b and 320b may be formed through an etching process using a single mask pattern, that is, the second mask pattern HM2. For example, the second mask pattern HM2 may be formed as a bar-type pillar, resulting in the first and second electrode protrusions 310b and 320b each being etched in an asymmetrical shape (in the first direction).

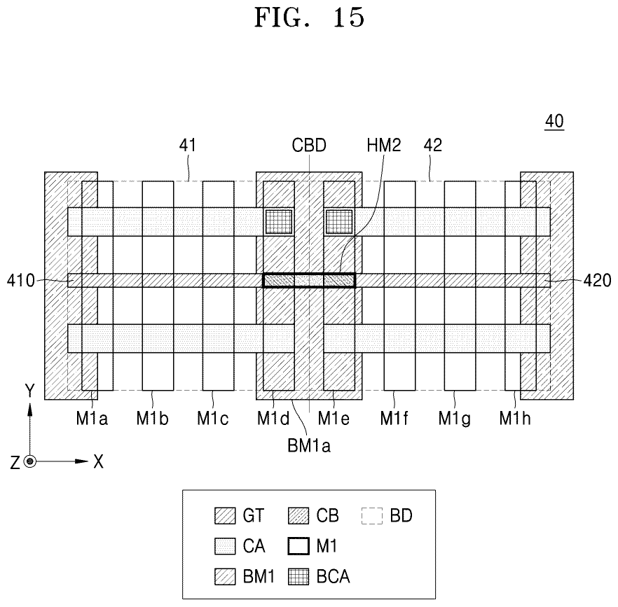

FIG. 15 is a layout illustrating an integrated circuit device 40 according to some embodiments.

Referring to FIG. 15, the integrated circuit device 40 may include a first standard cell 41 and a second standard cell 42 that are adjacent to each other in the first direction. For example, the first and second standard cells 41 and 42 may correspond to modification examples of the first and second standard cells 31 and 32 described with reference to FIG. 11. Each of the first and second standard cells 41 and 42 may include GAA transistors such as forksheet transistors or MBCFETs. The descriptions provided with reference to FIGS. 11, 12, 13A, 13B, 13C, 13D, and 14 may also apply to the current embodiment.

The integrated circuit device 40 may include a front side wiring layer, such as a first metal layer M1, and a backside wiring layer, such as a first backside metal layer BM1, and a PDN may be implemented using the front side wiring layer and/or the backside wiring layer. Some of signals and/or power applied to the integrated circuit device 40 may be transmitted through the first metal layer M1, that is, an FSPDN, and/or through the first backside metal layer BM1, that is, a BSPDN. Therefore, compared to a structure in which wiring is provided only on a front side of a substrate, the current embodiment may significantly reduce routing complexity and the length of each wire or via, thereby improving the performance of the integrated circuit device 40.

The first backside metal layer BM1 may include a first backside wiring pattern BM1a extending in the second direction and overlapping a cell boundary CBD (in the vertical direction). The first backside wiring pattern BM1a may be (electrically) connected to source/drains included in the first and second standard cells 41 and 42 through backside contacts BCA. The backside contacts BCA may be disposed on (above) the first backside metal layer BM1 and may extend into (extend through) a substrate in the vertical direction.

The first standard cell 41 may include a first gate electrode 410 extending in the first direction, and the second standard cell 42 may include a second gate electrode 420 extending in the first direction. The first and second gate electrodes 410 and 420 may be implemented similarly to (or same as) the first and second gate electrodes 310 and 320 described with reference to FIG. 11. That is, the first gate electrode 410 may include a first electrode body and a first electrode protrusion on (above) the first electrode body, and the second gate electrode 420 may include a second electrode body and a second electrode protrusion on (above) the second electrode body. The first and second electrode protrusions may be formed through an etching process using a second mask pattern HM2 and may thus have asymmetrical shapes based on the cell boundary CBD (in the first direction).

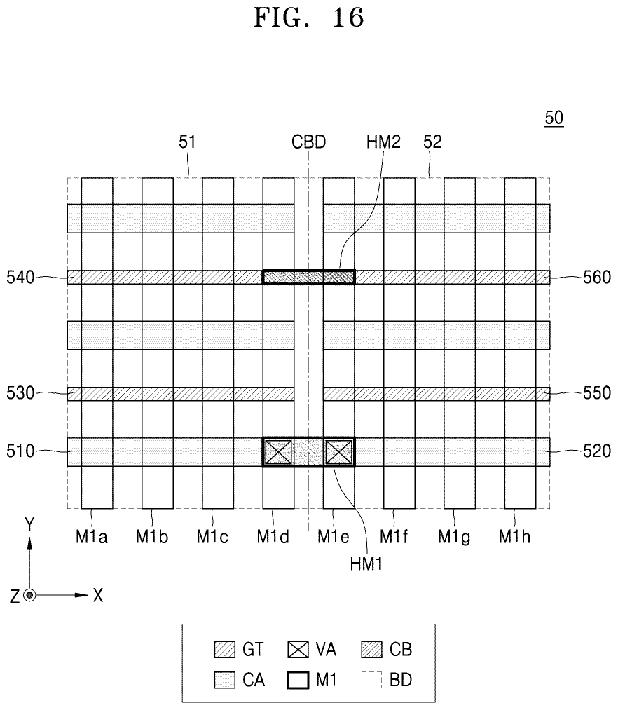

FIG. 16 is a layout illustrating an integrated circuit device 50 according to some embodiments.

Referring to FIG. 16, the integrated circuit device 50 may include a first standard cell 51 and a second standard cell 52 that are adjacent to each other in the first direction. For example, the first and second standard cells 51 and 52 may each include GAA transistors such as forksheet transistors or MBCFETs. The integrated circuit device 50 may include gate electrodes GT, contacts CA, vias VA, gate contacts CB, and a first metal layer M1. The first metal layer M1 may include first metal lines M1a, M1b, M1c, and M1d each extending on (above) the first standard cell 51 in the second direction, and second metal lines M1e, M1f, M1g, and M1h each extending on (above) the second standard cell 52 in the second direction. Thus, each of the first and second standard cells 51 and 52 may have a 4-track structure.

Each of the first and second standard cells 51 and 52 may include contacts CA extending in the first direction. For example, the first standard cell 51 may include a first contact 510, and the second standard cell 52 may include a second contact 520. The first and second contacts 510 and 520 may be apart from each other in the first direction. For example, each of the first and second contacts 510 and 520 may be implemented similarly to (or same as) the first and second contacts 110 and 120 described with reference to FIG. 1.

The first contact 510 may include a first contact body extending in the first direction and a first contact protrusion protruding from an upper surface of the first contact body. The second contact 520 may include a second contact body extending in the first direction and a second contact protrusion protruding from an upper surface of the second contact body. The first and second contact protrusions may correspond to vias VA and may be formed through an etching process using a first mask pattern HM1. Thus, the first and second contact protrusions may be asymmetrically etched based on a cell boundary CBD and may each have an asymmetrical shape in the first direction.

The first standard cell 51 may include first gate electrodes 530 and 540 extending in the first direction and separated from each other in the second direction, and the second standard cell 52 may include second gate electrodes 550 and 560 extending in the first direction and separated from each other in the second direction. The first and second gate electrodes 530 and 550 may be apart from each other in the first direction, and the first and second gate electrodes 540 and 560 may also be apart from each other in the first direction. For example, the first and second gate electrodes 540 and 560 may be implemented similarly to (or same as) the first and second gate electrodes 310 and 320 described with reference to FIG. 11.

The first gate electrode 540 may include a first electrode body extending in the first direction and a first electrode protrusion protruding from an upper surface of the first electrode body, and the second gate electrode 560 may include a second electrode body extending in the first direction and a second electrode protrusion protruding from an upper surface of the second electrode body. The first and second electrode protrusions may correspond to gate contacts CB and may be formed through an etching process using a second mask pattern HM2. Thus, the first and second electrode protrusions may be asymmetrically etched based on the cell boundary CBD and may each have an asymmetrical shape in the first direction. In an embodiment, upper surfaces of the first and second contact protrusions may be at the same level as (may be coplanar with) upper surfaces of the first and second electrode protrusions.

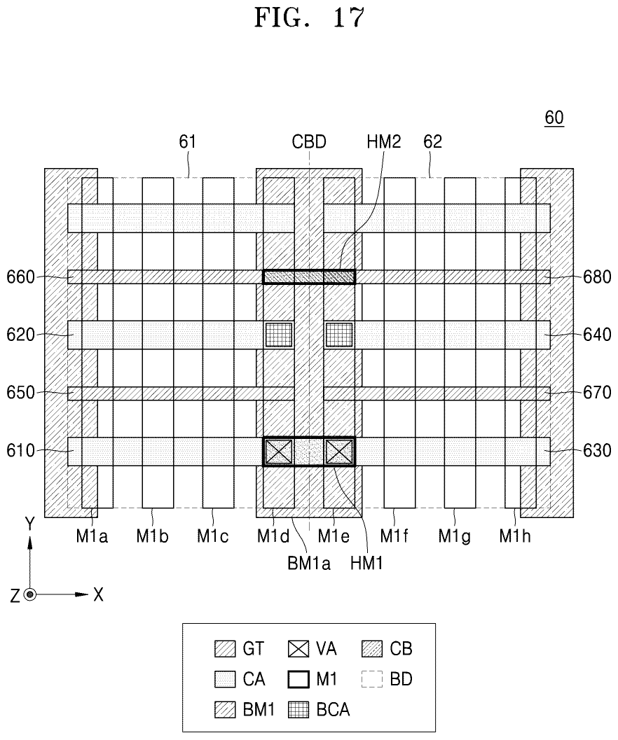

FIG. 17 is a layout illustrating an integrated circuit device 60 according to some embodiments.

Referring to FIG. 17, the integrated circuit device 60 may include a first standard cell 61 and a second standard cell 62 that are adjacent to each other in the first direction. For example, each of the first and second standard cells 61 and 62 may include GAA transistors such as forksheet transistors or an MBCFETs. The integrated circuit device 60 may include gate electrodes GT, contacts CA, vias VA, gate contacts CB, a first metal layer M1, backside contacts BCA, and a first backside wiring layer BM1. The first metal layer M1 may include first metal lines M1a, M1b, M1c, and M1d each extending in the second direction on (above) the first standard cell 61, and second metal lines M1e, M1f, M1g, and M1h each extending in the second direction on (above) the second standard cell 62. Thus, each of the first and second standard cells 61 and 62 may have a 4-track structure.

The first standard cell 61 may include first contacts 610 and 620, and the second standard cell 62 may include second contacts 630 and 640. For example, the first and second contacts 610 and 630 may be apart from each other in the first direction. For example, the first and second contacts 610 and 630 may be implemented similarly to (or same as) the first and second contacts 110 and 120 described with reference to FIG. 1. For example, the first and second contacts 620 and 640 may be implemented similarly to (or same as) the contacts 220 and 240 described with reference to FIG. 9.

For example, the first contact 610 may include a first contact body extending in the first direction and a first contact protrusion protruding from an upper surface of the first contact body, and the second contact 630 may include a second contact body extending in the first direction and a second contact protrusion protruding from an upper surface of the second contact body. The first and second contact protrusions may correspond to vias VA and may be formed through an etching process using a first mask pattern HM1. Thus, the first and second contact protrusions may be asymmetrically etched based on a cell boundary CBD and may each have an asymmetrical shape in the first direction.

In an embodiment, the first standard cell 61 may include a first source/drain (for example, refer to the first source/drain SD1b shown in FIG. 10) under the first contact 620, and the second standard cell 62 may include a second source/drain (for example, refer to the second source/drain SD2b shown in FIG. 10) under the second contact 640. The first and second source/drains may receive power voltage or ground voltage from a first backside wiring pattern BM1a through the backside contacts BCA, and thus, the first and second contacts 620 and 640 may not be electrically connected to the first metal layer M1. However, the inventive concept is not limited thereto, and in some embodiments, the first and second contacts 620 and 640 may be electrically connected to the first metal layer M1 and may receive power voltage and/or ground voltage simultaneously from both the first backside wiring pattern BM1a and the first metal layer M1, further improving the performance of the integrated circuit device 60.

In an embodiment, the first standard cell 61 may include a third source/drain under the first contact 610, and the second standard cell 62 may include a fourth source/drain under the second contact 630. The third and fourth source/drains may receive power voltage or ground voltage from the first backside wiring pattern BM1a through the backside contacts BCA. As described above, because the first and second contacts 610 and 630 may receive power voltage and/or ground voltage simultaneously from both the first backside wiring pattern BM1a and the first metal layer M1, the performance of the integrated circuit device 60 may be further improved.

The first standard cell 61 may include first gate electrodes 650 and 660 extending in the first direction and separated from each other in the second direction, and the second standard cell 62 may include second gate electrodes 670 and 680 extending in the first direction and separated from each other in the second direction. The first and second gate electrodes 650 and 670 may be apart from each other in the first direction, and the first and second gate electrodes 660 and 680 may also be apart from each other in the first direction. For example, the first and second gate electrodes 660 and 680 may be implemented similarly to (or same as) the first and second gate electrodes 310 and 320 described with reference to FIG. 11.

The first gate electrode 660 may include a first electrode body extending in the first direction and a first electrode protrusion protruding from an upper surface of the first electrode body, and the second gate electrode 680 may include a second electrode body extending in the first direction and a second electrode protrusion protruding from an upper surface of the second electrode body. The first and second electrode protrusions may correspond to gate contacts CB and may be formed through an etching process using a second mask pattern HM2. Thus, the first and second electrode protrusions may be asymmetrically etched based on the cell boundary CBD and may each have an asymmetrical shape in the first direction. In an embodiment, upper surfaces of the first and second contact protrusions may be at the same level as (may be coplanar with) upper surfaces of the first and second electrode protrusions.

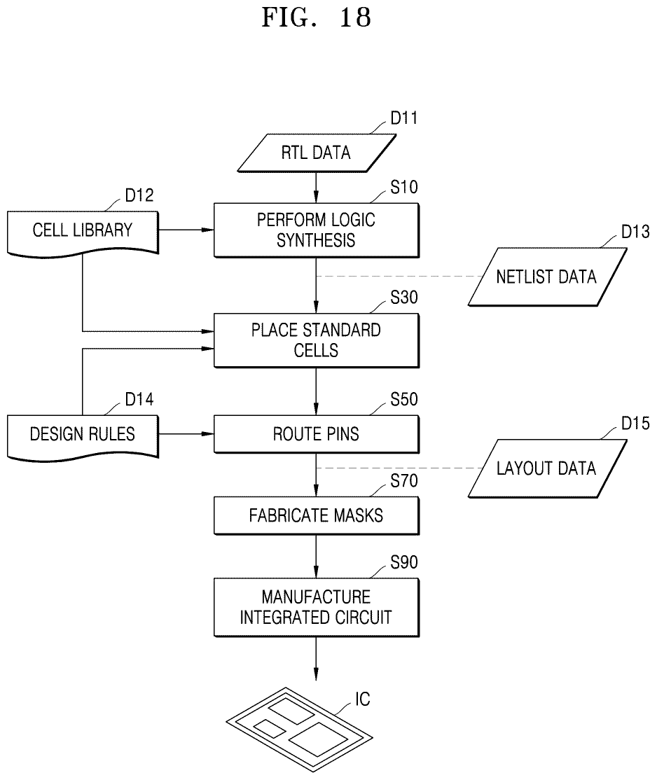

FIG. 18 is a flowchart illustrating a method of manufacturing an integrated circuit device according to some embodiments.

Referring to FIG. 18, the method of the current embodiment is for manufacturing an integrated circuit IC including standard cells and may include a plurality of operations S10, S30, S50, S70, and S90. A cell library (or standard cell library) D12 may include information about standard cells, such as information about functions, characteristics, and layouts of standard cells. In an embodiment, the cell library D12 may define functional cells that generate output signals from input signals, and may also define tap cells, filler cells, and dummy cells. Design rules D14 may include requirements that layouts of the integrated circuit IC may comply with. For example, the design rules D14 may include requirements for spacing between patterns in the same layer, a minimum pattern width, and routing directions of wiring layers.

In operation S10, a logic synthesis operation may be performed to generate netlist data D13 from register-transfer level (RTL) data D11. For example, a semiconductor design tool (for example, a logic synthesis tool) may perform logic synthesis by referencing the cell library D12 based on the RTL data D11 written in hardware description language (HDL) such as very high speed integrated circuit (VHSIC) hardware description language (VHDL) or Verilog, and may generate the netlist data D13 including a bitstream or netlist. The netlist data D13 may correspond to an input for placement and routing that are described below.

In operation S30, standard cells may be placed. For example, a semiconductor design tool (for example, a place and route (P&R) tool) may place standard cells used in the netlist data D13 by referencing the cell library D12. In operation S50, pins of the standard cells may be routed. For example, a semiconductor design tool may generate interconnections that electrically connect output pins and input pins of the placed standard cells and may generate layout data D15 defining the placed standard cells and the generated interconnections. The interconnections may include vias of a via layer and/or patterns of wiring layers. The wiring layers may include a front side wiring layer disposed above a front side of a substrate, and a backside wiring layer disposed on a backside of the substrate. The layout data D15 may have a format such as graphic design system II (GDSII) and may include geometric information about the standard cells and the interconnections. The semiconductor design tool may reference the design rules D14 while routing the pins of the standard cells. The layout data D15 may correspond to an output of placement and routing. Operation S50 alone, or operations S30 and S50 collectively, may be referred to as a method of designing an integrated circuit.

As illustrated in FIGS. 1-3,4A, 4B, 4C, 4D, 5-12, 13A, 13B, 13C, 13D, and 14-17, the integrated circuit device may include a plurality of standard cells, and a plurality of metal lines or wiring lines may be disposed above the standard cells. Each of the standard cells may include a contact plug that is in contact with a lower surface of a metal line. For example, the contact plug may include a via (for example, refer to the vias VA shown in FIG. 1) above a source/drain contact, or a source/drain contact. For example, the contact plug may include a gate contact (for example, refer to the gate contacts CB shown in FIG. 11) above a gate electrode. Depending on embodiments, the contact plug may be referred to as a pickup structure or a metal line pickup structure.

In some embodiments, first and second standard cells may be adjacent to each other in the first direction, with the first standard cell including a first contact plug adjacent to a cell boundary and the second standard cell including a second contact plug adjacent to the cell boundary. In this case, the first and second contact plugs may be formed through an etching process using a single bar-type mask pattern overlapping the first and second contact plugs. For example, source/drain contacts respectively included in the first and second standard cells may be separated from each other and may have asymmetrical shapes owing to an insulating wall or insulating layer overlapping the cell boundary. For example, gate electrodes respectively included in the first and second standard cells may be separated from each other and may have asymmetrical shapes owing to the insulating wall or insulating layer overlapping the cell boundary.

In operation S70, masks may be fabricated. For example, optical proximity correction (OPC) may be applied to the layout data D15 to correct distortion phenomena caused by light characteristics (such as refraction) in photolithography. Based on the layer data D15 to which OPC is applied, patterns may be defined on masks to form patterns on a plurality of layers. At least one mask (or photomask) may be fabricated for forming patterns on a plurality of layers.

In operation S90, an integrated circuit IC may be manufactured. For example, the integrated circuit IC may be manufactured by patterning a plurality of layers using the at least one mask fabricated in operation S70. A front-end-of-line (FEOL) may include operations such as an operation of planarizing and cleaning a wafer, an operation of forming trenches, an operation of forming wells, an operation of forming gate electrodes, and an operation of forming source and drain regions. Through the FEOL, individual devices such as transistors, capacitors, and resistors may be formed on the substrate. In addition, a back-end-of-line (BEOL) may include operations such as an operation of silicidazing gate, source, and drain regions, an operation of adding a dielectric, a planarization operation, an operation of forming holes, a process of adding metal layers, an operation of forming vias, and an operation of forming a passivation layer. Through the BEOL, the individual devices, such as transistors, capacitors, and resistors, may be connected to each other. In some embodiments, a middle-of-line (MOL) may be performed between the FEOL and the BEOL, and contacts may be formed above the individual devices. Subsequently, the integrated circuit IC may be packaged in a semiconductor package and used as a component in various applications.

While the inventive concept has been particularly shown and described with reference to embodiments thereof, it will be understood that various changes in form and details may be made therein without departing from the scope of the following claims.

What is claimed is:

1. An integrated circuit device comprising:
a first standard cell that comprises a first nanosheet stack, a first source/drain that is electrically connected to the first nanosheet stack, and a first contact on the first source/drain;
a second standard cell that comprises a second nanosheet stack, a second source/drain that is electrically connected to the second nanosheet stack, and a second contact on the second source/drain, wherein the second standard cell is adjacent to the first standard cell in a first direction; and
an insulating layer that extends in a vertical direction and overlaps a cell boundary in the vertical direction between the first standard cell and the second standard cell in the first direction,
wherein the vertical direction intersects the first direction,
wherein the first contact comprises a first contact body that extends in the first direction and a first contact protrusion that protrudes from an upper surface of the first contact body in the vertical direction,
wherein the second contact comprises a second contact body that extends in the first direction and a second contact protrusion that protrudes from an upper surface of the second contact body in the vertical direction, and
wherein the first contact protrusion and the second contact protrusion are spaced apart from each other in the first direction with the insulating layer therebetween, and each of the first contact protrusion and the second contact protrusion has an asymmetrical shape in the first direction.

2. The integrated circuit device of claim 1, wherein the first contact has a single body without an interface between the first contact body and the first contact protrusion.

3. The integrated circuit device of claim 1, wherein the first standard cell further comprises a first gate electrode that extends around the first nanosheet stack,
wherein the second standard cell further comprises a second gate electrode that extends around the second nanosheet stack,
wherein the first gate electrode comprises a first electrode body that extends in the first direction and a first electrode protrusion that protrudes from an upper surface of the first electrode body in the vertical direction,
wherein the second gate electrode comprises a second electrode body that extends in the first direction and a second electrode protrusion that protrudes from an upper surface of the second electrode body in the vertical direction, and
wherein the first electrode protrusion and the second electrode protrusion are spaced apart from each other with the insulating layer therebetween in the first direction and each of the first electrode protrusion and the second electrode protrusion has an asymmetrical shape in the first direction.

4. The integrated circuit device of claim 3, wherein the first gate electrode has a single body without an interface between the first electrode body and the first electrode protrusion.

5. The integrated circuit device of claim 3, wherein an upper surface of the first contact protrusion, an upper surface of the second contact protrusion, an upper surface of the first electrode protrusion, and an upper surface of the second electrode protrusion are coplanar with each other.

6. The integrated circuit device of claim 1, further comprising a first metal layer above the first standard cell and the second standard cell,
wherein the first metal layer comprises:
first metal lines that each extend above the first standard cell in a second direction that intersects the first direction and the vertical direction; and
second metal lines that each extend above the second standard cell in the second direction, and
wherein a first number of the first metal lines and a second number of the second metal lines are equal.

7. The integrated circuit device of claim 6, wherein each of the first number and the second number is four.

8. The integrated circuit device of claim 6, wherein the first metal lines and the second metal lines are free of overlap with the cell boundary in the vertical direction.

9. An integrated circuit device comprising:
a first standard cell that comprises a first nanosheet stack, a first source/drain that is electrically connected to the first nanosheet stack, and a first gate electrode that extends around the first nanosheet stack;
a second standard cell that comprises a second nanosheet stack, a second source/drain that is electrically connected to the second nanosheet stack, and a second gate electrode that extends around the second nanosheet stack, wherein the second standard cell is adjacent to the first standard cell in a first direction; and
an insulating layer that extends in a vertical direction and overlaps a cell boundary in the vertical direction between the first standard cell and the second standard cell in the first direction,
wherein the vertical direction intersects the first direction,
wherein the first gate electrode comprises a first electrode body that extends in the first direction and a first electrode protrusion that protrudes from an upper surface of the first electrode body in the vertical direction,
wherein the second gate electrode includes a second electrode body that extends in the first direction and a second electrode protrusion that protrudes from an upper surface of the second electrode body in the vertical direction, and
wherein the first electrode protrusion and the second electrode protrusion are spaced apart from each other in the first direction with the insulating layer therebetween, and each of the first electrode protrusion and the second electrode protrusion has an asymmetrical shape in the first direction.

10. The integrated circuit device of claim 9, wherein the first gate electrode has a single body without an interface between the first electrode body and the first electrode protrusion.

11. The integrated circuit device of claim 9, wherein the first standard cell further comprises a first contact on the first source/drain,
wherein the second standard cell further comprises a second contact on the second source/drain,
wherein the first contact comprises a first contact body that extends in the first direction and a first contact protrusion that protrudes from an upper surface of the first contact body in the vertical direction,
wherein the second contact comprises a second contact body that extends in the first direction and a second contact protrusion that protrudes from an upper surface of the second contact body in the vertical direction, and
wherein the first contact protrusion and the second contact protrusion are spaced apart from each other with the insulating layer therebetween in the first direction and each of the first contact protrusion and the second contact protrusion has an asymmetrical shape in the first direction.

12. The integrated circuit device of claim 11, wherein the first contact has a single body without an interface between the first contact body and the first contact protrusion.

13. The integrated circuit device of claim 11, wherein an upper surface of the first contact protrusion, an upper surface of the second contact protrusion, an upper surface of the first electrode protrusion, and an upper surface of the second electrode protrusion are coplanar with each other.

14. The integrated circuit device of claim 9, further comprising: a first metal layer above the first standard cell and the second standard cell,
wherein the first metal layer comprises:
first metal lines that each extend above the first standard cell in a second direction that intersects the first direction and the vertical direction; and
second metal lines that each extend above the second standard cell in the second direction, and
wherein a first number of the first metal lines and a second number of the second metal lines are equal.

15. The integrated circuit device of claim 14, wherein each of the first number and the second number is four.

16. The integrated circuit device of claim 14, wherein the first metal lines and the second metal lines are free of overlap with the cell boundary in the vertical direction.

17. An integrated circuit device comprising:
a first nanosheet stack and a second nanosheet stack on active regions of a substrate, wherein the first nanosheet stack and the second nanosheet stack are spaced apart from each other in a first direction that is parallel with an upper surface of the substrate;
a first source/drain and a second source/drain that are electrically connected to the first nanosheet stack and the second nanosheet stack, respectively;
a first gate electrode and a second gate electrode that extend in the first direction, wherein the first gate electrode and the second gate electrode extend around the first nanosheet stack and the second nanosheet stack, respectively;
a first metal layer above the first gate electrode and the second gate electrode;
a first contact on the first source/drain, wherein the first contact comprises a first contact body that extends in the first direction and a first contact protrusion that protrudes from an upper surface of the first contact body in a vertical direction that is perpendicular to the upper surface of the substrate; and
a second contact on the second source/drain, wherein the second contact comprises a second contact body that extends in the first direction and a second contact protrusion that protrudes from an upper surface of the second contact body in the vertical direction,
wherein the first contact protrusion and the second contact protrusion are spaced apart from each other in the first direction and each of the first contact protrusion and the second contact protrusion has an asymmetrical shape in the first direction.

18. The integrated circuit device of claim 17, wherein the first gate electrode comprises a first electrode body that extends in the first direction and a first electrode protrusion that protrudes from an upper surface of the first electrode body in the vertical direction,
wherein the second gate electrode comprises a second electrode body that extends in the first direction and a second electrode protrusion that protrudes from an upper surface of the second electrode body in the vertical direction, and
wherein the first electrode protrusion and the second electrode protrusion are spaced apart from each other in the first direction and each of the first electrode protrusion and the second electrode protrusion has an asymmetrical shape in the first direction.

19. The integrated circuit device of claim 17, further comprising:
a third source/drain and a fourth source/drain that are electrically connected to the first nanosheet stack and the second nanosheet stack, respectively;
a backside wiring layer on a lower surface of the substrate; and
backside contacts on the backside wiring layer, wherein the backside contacts extend into the substrate in the vertical direction,
wherein the third source/drain and the fourth source/drain are electrically connected to the backside wiring layer through the backside contacts.

20. The integrated circuit device of claim 17, further comprising:
a backside wiring layer on a lower surface of the substrate; and
backside contacts on the backside wiring layer,
wherein the backside contacts extend into the substrate in the vertical direction,
wherein the first source/drain and the second source/drain are electrically connected to the backside wiring layer through the backside contacts.
